(19) United States
(12) Patent Application Publication
(10) Pub. No.: US 2019/0174631 A1
(43) Pub. Date: Jun. 6, 2019

(54) MINIATURIZED CIRCUIT AND METHOD OF MAKING THE SAME

(71) Applicant: SIWARD CRYSTAL TECHNOLOGY CO., LTD., Taichung City (TW)

(72) Inventors: Yen-Hao TSENG, Miaoli County (TW); Shih-Ying HUANG, Miaoli County (TW); Yu-Hsuan PENG, Miaoli County (TW); Wei-Chih HSU, Miaoli County (TW); Wei-Lin WANG, Miaoli County (TW); Wen-Kuan HUANG, Miaoli County (TW)

(21) Appl. No.: 16/156,920

(22) Filed: Oct. 10, 2018

(30) Foreign Application Priority Data
Dec. 4, 2017 (TW) 106142401

(51) Int. Cl. H05K 3/06; H05K 3/46; H05K 1/09

(52) U.S. Cl. CPC H05K 3/067; H05K 3/064; H05K 3/4661; H05K 2203/0723; H05K 2203/125; H05K 2203/0786; H05K 1/09

(57) ABSTRACT

A method for making a miniaturized circuit includes: depositing a bottom metal layer including a first metal on a substrate; forming a patterned photoresist layer on the bottom metal layer to expose a first portion of the bottom metal layer and to cover a second portion thereof; plating a middle circuit pattern including a second metal on the bottom metal layer to cover the first portion of the bottom metal layer; plating a top circuit pattern including a third metal different from the first metal onto the middle circuit pattern to cover the middle circuit pattern; removing the patterned photoresist layer; and etching the second portion of the bottom metal layer with an etchant, so as to pattern the bottom metal layer into a bottom circuit pattern.

### CROSS-REFERENCE TO RELATED APPLICATION

This application claims priority of Taiwanese Invention Patent Application No. 106142401, filed on Dec. 4, 2017.

### FIELD

The disclosure relates to a circuit and a method of making the same, and more particularly to a miniaturized circuit and a method of making the same.

### BACKGROUND

Referring to FIGS. 1 and 2, a conventional method of making a circuit 1 including the steps of: (A) depositing a bottom metal layer 120 made of copper (Cu) on a surface 111 of a substrate 11; (B) forming a patterned photoresist layer 13 on the bottom metal layer 120 such that a first portion 121 of the bottom metal layer 120 is exposed from the patterned photoresist layer 13 and a second portion 122 of the bottom metal layer 120 is covered by the patterned photoresist layer 13; (C) electroplating a top circuit pattern 14 made of Cu on the bottom metal layer 120 so that the first portion 121 of the bottom metal layer 120 is covered by the top circuit pattern 14; (D) removing the patterned photoresist layer 13 to expose the second portion 122 of the bottom metal layer 120; and (E) removing the second portion 122 of the bottom metal layer 120 from the substrate 11 using an etchant 15, so as to pattern the bottom metal layer 120 into a bottom circuit pattern 12. The circuit 1 having the top circuit pattern 14 deposited on the bottom circuit pattern 12 was thus produced (see FIG. 2).

However, when the etchant 15 is applied for a long time, the bottom metal layer 120 and the top circuit pattern 14 would be overetched during the etching step (E), resulting in formation of undesired undercuts 123 on the circuit 1. With increasing demand for portable electronic device, the circuits contained therein should meet downsizing requirement of being lightweight and thin. Once the circuit to be produced is required to have a line width of less than 10 μm, the aforementioned undercuts 123 may cause the circuits to be broken. As such, the conventional method as mentioned above would not be suitable for producing a circuit having a line width of less than 10 μm.

### SUMMARY

Therefore, an object of the disclosure is to provide a method for making a miniaturized circuit and a miniaturized circuit produced therefrom that can alleviate at least one of the drawbacks of the prior art.

According to this disclosure, the method for making a miniaturized circuit includes the steps of:

depositing a bottom metal layer on a surface of a substrate, the bottom metal layer including a first metal;

forming a patterned photoresist layer on the bottom metal layer such that a first portion of the bottom metal layer is exposed from the patterned photoresist layer and a second portion of the bottom metal layer is covered by the patterned photoresist layer;

plating a middle circuit pattern on the bottom metal layer so that the first portion of the bottom metal layer is covered by the middle circuit pattern, the middle circuit pattern including a second metal;

plating a top circuit pattern onto the middle circuit pattern so as to cover a portion of the middle circuit pattern that is not in contact with the bottom metal layer and the patterned photoresist layer, the top circuit pattern including a third metal different from the first metal;

removing the patterned photoresist layer to expose the second portion of the bottom metal layer; and

etching the second portion of the bottom metal layer with an etchant, so as to pattern the bottom metal layer into a bottom circuit pattern, the bottom circuit pattern being disposed underneath the middle circuit pattern.

According to the disclosure, the miniaturized circuit includes:

a substrate;

a bottom circuit pattern that is formed on a surface of the substrate and that includes a first metal;

a middle circuit pattern that is deposited on the bottom circuit pattern and that includes a second metal; and

a top circuit pattern that is deposited on the middle circuit pattern and covers a portion of the middle circuit pattern that is not in contact with the bottom circuit pattern, and that includes a third metal different from the first metal.

### BRIEF DESCRIPTION OF THE DRAWINGS

Other features and advantages of the disclosure will become apparent in the following detailed description of the embodiment (s) with reference to the accompanying drawings, of which:

FIG. 1 illustrates consecutive steps of a conventional method of making a circuit;

FIG. 2 is a schematic view illustrating a circuit made by the conventional method of FIG. 1;

FIGS. 3 and 4 are schematic views illustrating consecutive steps of an embodiment of a method of making a miniaturized circuit according to this disclosure; and

FIG. 5 is a schematic view illustrating a miniaturized circuit made by the embodiment of the method.

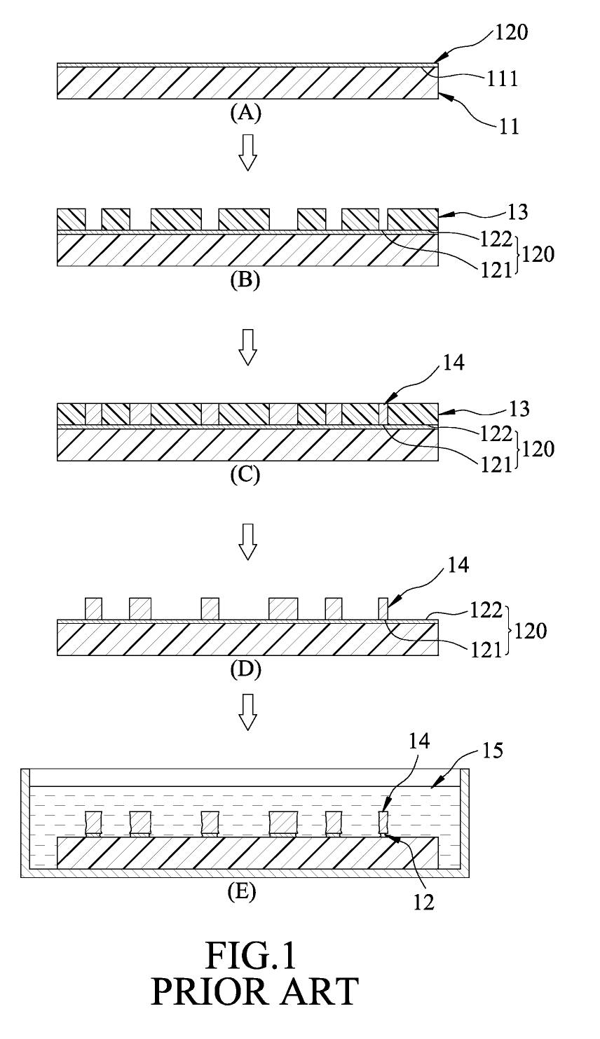

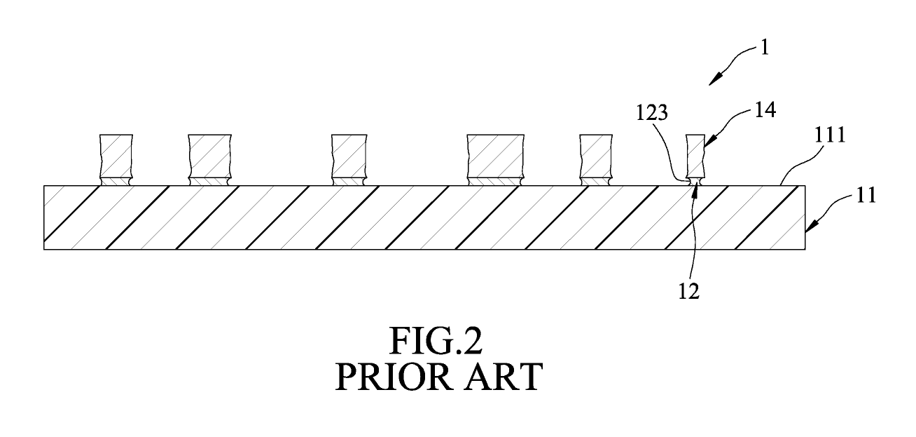

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

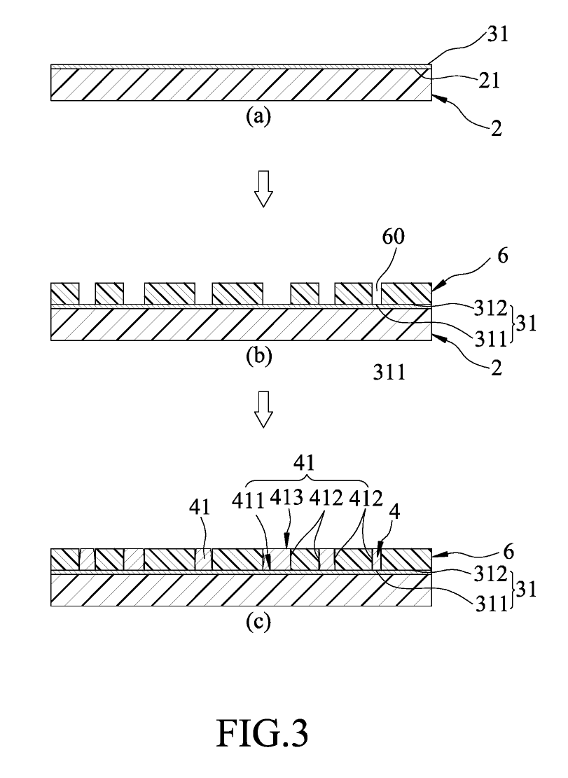

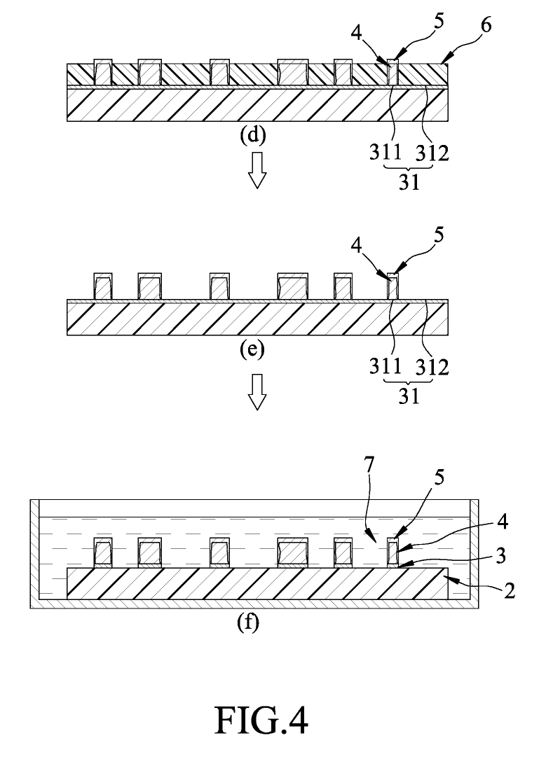

Referring to FIGS. 3 to 5, an embodiment of a method for making a miniaturized circuit according to the disclosure includes the following consecutive steps (a) to (f).

Step (a): depositing a bottom metal layer 31 on a surface 21 of a substrate 2. The bottom metal layer 31 includes a first metal. In this embodiment, the bottom metal layer 31 is deposited using a sputtering technique.

Step (b): forming a patterned photoresist layer 6 on the bottom metal layer 31 such that a first portion 311 of the bottom metal layer 31 is exposed from the patterned photoresist layer 6 and a second portion 312 of the bottom metal layer 31 is covered by the patterned photoresist layer 6.

Step (c): plating a middle circuit pattern 4 on the bottom metal layer 31 so that the first portion 311 of the bottom metal layer 31 is covered by the middle circuit pattern 4. To be specific, the patterned photoresist layer 6 and the first portion 311 of the bottom metal layer 31 corporately define a space 60, and the middle circuit pattern 4 are deposited in the space 60. The middle circuit pattern 4 includes a second metal. The middle circuit pattern 4 may be plated using any well known techniques, such as electroplating and electroless plating.

It is noted that the middle circuit pattern 4 would not be entirely filled in the space 60 due to the incomplete metal deposition, and therefore gaps will be generated between a peripheral portion of the middle circuit pattern 4 and the patterned photoresist layer 6. To be specific, the middle circuit pattern 4 includes a plurality of circuit trace portions 41. Each circuit trace portion 41 has a bottom surface 411 that is in contact with the bottom metal layer 31, a top surface 413 opposite to the bottom surface 411, and a lateral surface 412 interconnecting the top and bottom surfaces 411, 413. The gaps would be formed between the patterned photoresist layer 6 and the lateral surfaces 412 of some or all of the circuit trace portions 41. The lateral surfaces 412 are composed of the peripheral portion of the middle circuit pattern 4.

Step (d): plating a top circuit pattern 5 onto the middle circuit pattern 4 so as to cover a portion of the middle circuit pattern 4 that is not in contact with the bottom metal layer 31 and the patterned photoresist layer 6. In other words, the top circuit pattern 5 is formed on a top portion of the middle circuit pattern 4 opposite to the bottom metal layer 31, and fills the gaps between the middle circuit pattern 4 and the patterned photoresist layer 6. The top circuit pattern 5 includes a third metal that is different from the first metal of the bottom metal layer 31. The top circuit pattern 5 may be plated using any well known techniques, such as electroplating and electroless plating.

Step (e): removing the patterned photoresist layer 6 to expose the second portion 312 of the bottom metal layer 31.

Step (f): etching the second portion 312 of the bottom metal layer 31 with an etchant 7, so as to pattern the bottom metal layer 31 into a bottom circuit pattern 3. The bottom circuit pattern 3 is disposed underneath the middle circuit pattern 4.

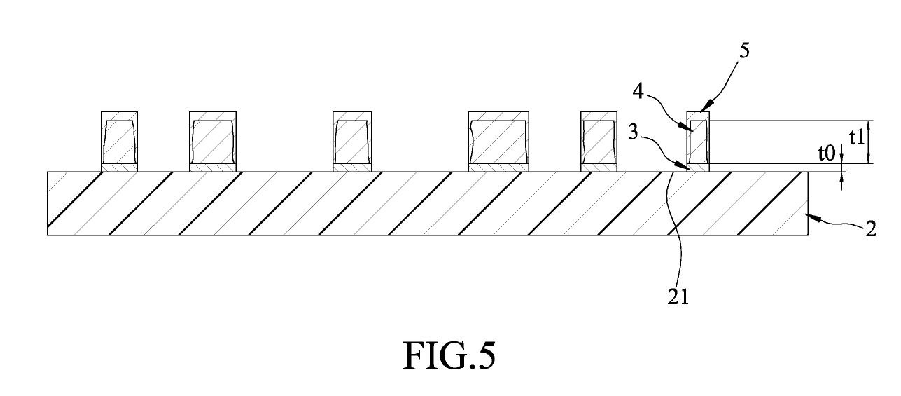

Accordingly, the miniaturized circuit obtained from the method of this disclosure includes the substrate 2, the bottom circuit pattern 3, the middle circuit pattern 4 and the top circuit pattern 5 (see FIG. 5).

The bottom circuit pattern 3 is formed on the surface 21 of the substrate 2 and includes the first metal.

The middle circuit pattern 4 is deposited on the bottom circuit pattern 3 and includes the second metal.

The top circuit pattern 5 includes the third metal different from the first metal, and is deposited on the middle circuit pattern 4 and covers the portion of the middle circuit pattern 4 that is not in contact with the bottom circuit pattern 3. To be specific, the top circuit pattern 5 covers the top portion and at least a part of the peripheral portion of the middle circuit pattern 4.

According to this disclosure, the etchant 7 etches the first metal at a first rate R1 and etches the third metal at a second rate R2, R1 being higher than R2. In certain embodiments, the ratio of R1 to R2 is not lower than 100.

Examples of the first metal suitable for use in this disclosure may be Cu, Au or the combination thereof. Examples of the second metal suitable for use in this disclosure may be Cu, Au or the combination thereof. Example of the third metal suitable for use in this disclosure may be Ni. In certain embodiments, the etchant 7 is an aqueous solution including ceric ammonium nitrate. In an exemplary embodiment, the etchant 7 is an aqueous solution of ceric ammonium nitrate.

In this embodiment, the bottom metal layer 31 is a Cu layer and is formed using a sputtering technique. The middle circuit pattern 4 was electroplated on the bottom metal layer 31 using a copper electroplating solution (Copper Gleam™ ST-901, available from Rohm and Hass Electronic Materials Co., Ltd.). The top circuit pattern 5 was electrolessly plated on the middle circuit pattern 4 using an electroless nickel plating solution (Cat. No. NMP-1-M, available from Taiwan Uyemura Co., Ltd.).

In this embodiment, the etchant 7 is an aqueous solution of ceric ammonium nitrate, and the concentration of ceric ammonium nitrate in the aqueous solution ranges from 5 wt % to 10 wt %. Since the etching rate of Cu in the aqueous solution of ceric ammonium nitrate is significantly higher than that of Ni, the top circuit pattern 5 may protect the peripheral portion of the middle circuit pattern 4 from being etched by the etchant 7, thereby preventing the formation of undercuts on the miniaturized circuit.

According to this disclosure, the bottom circuit pattern 3 has a thickness t₀, and the middle circuit pattern 4 has a thickness t₁, t₀ being smaller than t₁. In certain embodiments, t₀ ranges from 100 nm to 200 nm, and t₁ ranges from 5 μm to 15 μm. In this embodiment, t₀ is about 150 nm, and t₁ is about 10 μm.

In summary, by covering the portion of the middle circuit pattern 4 that is not in contact with the bottom circuit pattern 3 with the top circuit pattern 5, and by controlling the etching rate as well as the thickness of the bottom circuit pattern 3 and the middle circuit pattern 4, lateral etching of the bottom and middle circuit patterns 3, 4 by the etchant 7 could be greatly reduced, thereby preventing the formation of the undercuts that may cause the circuits to be broken.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the di s closure has been described in connection with what are considered the exemplary embodiments, it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for making a miniaturized circuit, comprising the steps of:
depositing a bottom metal layer on a surface of a substrate, the bottom metal layer including a first metal;
forming a patterned photoresist layer on the bottom metal layer such that a first portion of the bottom metal layer is exposed from the patterned photoresist layer and a second portion of the bottom metal layer is covered by the patterned photoresist layer;
plating a middle circuit pattern on the bottom metal layer so that the first portion of the bottom metal layer is covered by the middle circuit pattern, the middle circuit pattern including a second metal;
plating a top circuit pattern onto the middle circuit pattern so as to cover a portion of the middle circuit pattern that is not in contact with the bottom metal layer and the patterned photoresist layer, the top circuit pattern including a third metal different from the first metal;
removing the patterned photoresist layer to expose the second portion of the bottom metal layer; and
etching the second portion of the bottom metal layer with an etchant, so as to pattern the bottom metal layer into a bottom circuit pattern, the bottom circuit pattern being disposed underneath the middle circuit pattern.

2. The method of claim 1, wherein the etchant etches the first metal at a first rate R1 and etches the third metal at a second rate R2, R1 being higher than R2.

3. The method of claim 2, wherein the ratio of R1 to R2 is not lower than 100.

4. The method of claim 2, wherein the first and second metals are independently selected from the group consisting of Cu, Au and the combination thereof, and the third metal is Ni.

5. The method of claim 4, wherein the etchant is an aqueous solution including ceric ammonium nitrate.

6. The method of claim 5, wherein each of the first and second metals is Cu, and the concentration of ceric ammonium nitrate in the aqueous solution ranges from 5 wt % to 10 wt %.

7. The method of claim 1, wherein the bottom circuit pattern has a thickness t₀, and the middle circuit pattern has a thickness t₁, t₀ being smaller than t₁.

8. The method of claim 1, wherein t₀ ranges from 100 nm to 200 nm, and t₁ ranges from 5 μm to 15 μm.

9. A miniaturized circuit comprising:
a substrate;
a bottom circuit pattern that is formed on a surface of said substrate and that includes a first metal;
a middle circuit pattern that is deposited on said bottom circuit pattern and that includes a second metal; and
a top circuit pattern that is deposited on said middle circuit pattern and covers a portion of the middle circuit pattern that is not in contact with the bottom circuit pattern, and that includes a third metal different from said first metal.

10. The miniaturized circuit of claim 9, wherein said first and second metals are independently selected from the group consisting of Cu, Au and the combination thereof, and said third metal is Ni.

11. The miniaturized circuit of claim 9, wherein said bottom circuit pattern has a thickness t₀, and said middle circuit pattern has a thickness t₁, t₀ being smaller than t₁.

12. The miniaturized circuit of claim 11, wherein t₀ ranges from 100 nm to 200 nm, and t₁ ranges from 5 μm to 15 μm.
